(19) United States
(12) Patent Application Publication
(10) Pub. No.: US 2026/0038628 A1
(43) Pub. Date: Feb. 5, 2026

(54) DETECTION AND RETIREMENT OF DEFECTIVE BLOCKS

(71) Applicant: Micron Technology, Inc., Boise, ID (US)

(72) Inventors: Amiya Banerjee, Bangalore (IN); Sampath K. Ratnam, San Jose, CA (US); Ashutosh Malshe, Fremont, CA (US)

(21) Appl. No.: 19/274,323

(22) Filed: Jul. 18, 2025

Related U.S. Application Data
(60) Provisional application No. 63/677,314, filed on Jul. 30, 2024.

(51) Int. Cl. G11C 29/00; G11C 29/02; G11C 29/52

(52) U.S. Cl. CPC G11C 29/883; G11C 29/022; G11C 29/52

(57) ABSTRACT

Methods, systems, and devices for detection and retirement of defective blocks are described. Techniques described herein may enable a memory system to determine if a block of memory cells may be partially retired. For example, the memory system may determine if an error correction counter has satisfied a first threshold or if a bit error rate (BER) of the block of memory cells satisfies a second threshold. The memory system may determine if a BER of one or more word lines of a first deck of the block of memory cells and a BER of one or more word lines of neighboring decks of the block of memory cells satisfy respective thresholds. The memory system may accordingly determine whether to refrain from retiring the block of memory cells, to partially retire the block of memory cells, or to fully retire the block of memory cells.

### CROSS REFERENCE

The present Application for Patent claims priority to U.S. Patent Application No. 63/677,314 by Banerjee et al., entitled “DETECTION AND RETIREMENT OF DEFECTIVE BLOCKS,” filed Jul. 30, 2024, which is assigned to the assignee hereof, and which is expressly incorporated by reference in its entirety herein.

### TECHNICAL FIELD

The following relates to one or more systems for memory, including detection and retirement of defective blocks.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports detection and retirement of defective blocks in accordance with examples as disclosed herein.

FIG. 2 shows an example of a process flow that supports detection and retirement of defective blocks in accordance with examples as disclosed herein.

FIG. 3 shows a block diagram of a memory system that supports detection and retirement of defective blocks in accordance with examples as disclosed herein.

FIG. 4 shows a flowchart illustrating a method or methods that support detection and retirement of defective blocks in accordance with examples as disclosed herein.

### DETAILED DESCRIPTION

Memory systems may include blocks of memory cells. As the size (e.g., storage capacity) of blocks increases, the relative significance of each block may also increase. For example, if a memory system includes relatively large blocks, retiring a single block from use may affect the memory system differently than if the same memory system included relatively smaller blocks. Thus, ensuring that blocks are not retired prematurely or belatedly is desirable. That is, if a block is retired prematurely, the premature retirement may result in the loss of a potentially good (e.g., valid) block. In other instances, belatedly retiring a block can lead to undesirable performance consequences, such as increased read latency and data loss. Accordingly, a memory system that retires blocks with more precision is desirable.

A memory system configured to ensure that blocks are retired when its defectiveness is confirmed is described herein. For example, a memory system may employ different types of error correction capabilities to identify (e.g., detect) and correct identified errors. In some instances, a memory system may perform a first type of error correction and, if unsuccessful, a second type of error correction. As described herein, if a memory system performs a second type of error correction, such as a redundant array of independent NAND (RAIN) error correction, the memory system may establish (and increment) a counter for the affected block. The memory system may compare a value of the counter and a bit error rate (BER) of the affected block to a threshold value to determine whether the block is defective. In some instances the memory system may employ one or more additional operations to determine whether the entire block is defective or whether a portion of the block is defective (e.g., whether the block is a half-good block (HGB) or a third-good block (TGB)). Based on the operations, the memory system may retire the entire block or otherwise operate the block as a HGB or a TGB. Such operations may ensure that blocks are retired when defective, which may improve the overall performance of the memory system.

In addition to applicability in memory systems as described herein, techniques for block retirement based on BERs may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling a memory system to correctly determine when a block of memory cells (e.g., or one or more decks of memory cells in a block of memory cells) may be retired, which may decrease processing or latency times, improve response times, or otherwise improve user experience, among other benefits.

In addition to applicability in memory systems as described herein, techniques for block retirement based on BERs may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by enabling a memory system to correctly determine when a block of memory cells (e.g., or one or more decks of memory cells in a block of memory cells) may not be retired, which may reduce electronic waste and extend the life of electronic devices, among other benefits.

Features of the disclosure are illustrated and described in the context of systems, devices, and circuits. Features of the disclosure are further illustrated and described in the context of process flows and flowcharts.

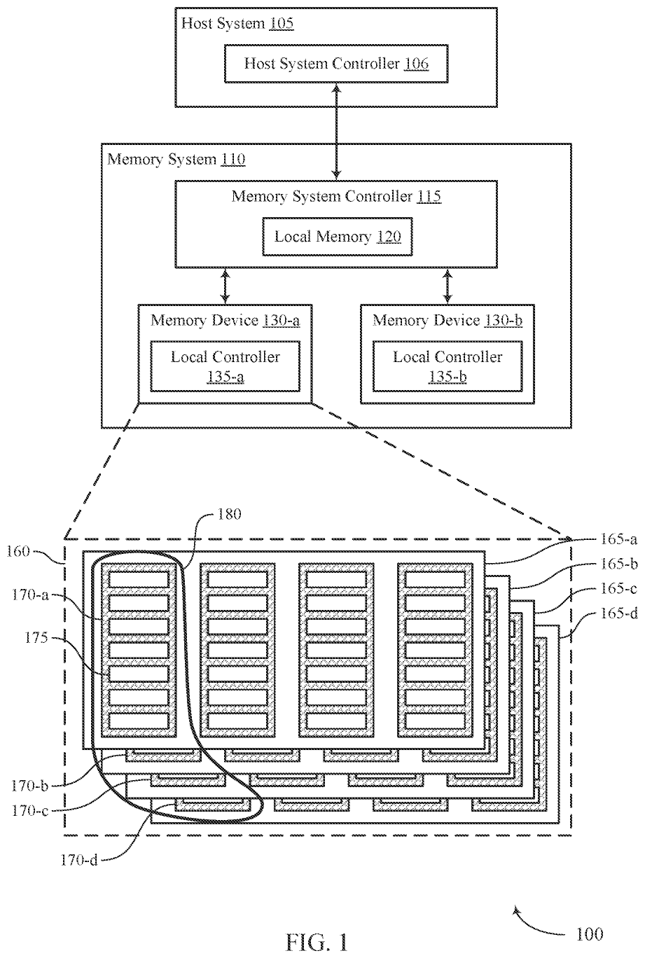

FIG. 1 shows an example of a system 100 that supports detection and retirement of defective blocks in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations-which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

The memory system 110 may employ different types of error correction capabilities to identify (e.g., detect) and correct identified errors. In some instances, the memory system controller 115 may perform a first type of error correction and, if unsuccessful, a second type of error correction on a block 170. As described herein, if the memory system controller 115 performs a second type of error correction, such as a RAIN error correction, the memory system controller 115 may establish (and increment) a counter for the affected block 170. The memory system controller 115 may compare a value of the counter and a BER of the affected block 170 to a threshold value to determine whether the block 170 is defective. In some instances the memory system controller 115 may employ one or more additional operations to determine whether the entire block 170 is defective or whether a portion of the block is defective (e.g., whether the block 170 is a HGB or a TGB). Based on the operations, the memory system controller 115 may retire the entire block 170 or otherwise operate the block 170 as a HGB or a TGB. Such operations may ensure that blocks are retired when defective, which may improve the overall performance of the memory system 110.

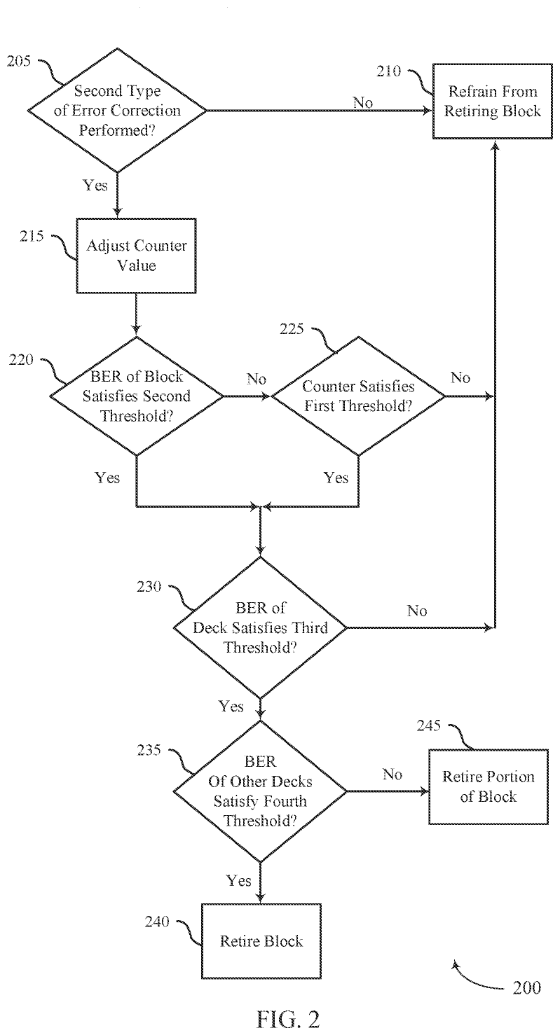

FIG. 2 shows an example of a process flow 200 that supports detection and retirement of defective blocks in accordance with examples as disclosed herein. The process flow 200 may implement or may be implemented by aspects of the system 100. For example, the process flow 200 may be implemented by the memory system 110 (e.g., a memory system controller 115 or a memory device 130) as described with reference to FIG. 1. The techniques described in the context of the process flow 200 may enable the memory system 110 to determine whether to retire some or all of a block of memory cells.

In the following description of the process flow 200, the operations may occur in a different order than the example order shown and, in some examples, may be performed by one or more different devices other than those described as examples. Some operations also may be omitted from the process flow 200, and other operations may be added to the process flow 200. Further, although some operations may be shown to occur at different times for discussion purposes, these operations may actually occur at the same time. Although the described techniques are described in the context of being performed by a memory system 110, in some examples, the described techniques may be performed by one or more components of the memory system 110. For example, as described herein, an operation performed by the memory system 110 may be performed by a memory system controller 115 of the memory system 110.

As described with reference to the system 100, a memory system 110 may include one or more blocks of memory cells. In some examples, a size of the block of memory cells may increase a significance of the block of memory cells. That is, if the memory system 110 retires a relatively larger block of memory cells, the memory system 110 may retire a relatively larger quantity of memory cells, which may affect the storage capacity of the memory system 110. That is, if a block is retired prematurely, the premature retirement may result in the loss of a potentially good (e.g., valid) block. In other instances, belatedly retiring a block can lead to undesirable performance consequences, such as increased read latency and data loss. Accordingly, the techniques described herein may ensure that blocks are retired when defective, which may improve the overall performance of the memory system 110.

At 205, the memory system 110 may determine whether a second type of error correction operation (e.g., a RAIN error correction operation) has been triggered based on performing a first type of error correction operation on a block of memory cells. That is the memory system 110 may identify an error associated with one or more blocks, and may perform a first type of error correction operation to correct the error(s).

In some examples, the first error correction operation may be an operation configured to correct a first quantity of bit errors, and the second error correction operation may be an operation configured to correct a second quantity of bit errors that is greater than the first quantity. The second type of error correction operation may be triggered based on the first type of error correction operation unsuccessfully correcting the error(s). For example, the first type of error correction may refer to an on-die error correction code (ECC), and the second type of error correction may refer to a RAIN error correction operation that is configured to correct a greater quantity of bit-errors than on-die ECC. If the second type of error correction has not been triggered, the memory system 110 may not perform the second type of error correction (e.g., the error(s) may have been corrected) and, at 210, the memory system 110 may refrain from retiring the block of memory cells.

In some examples, one or more conditions (e.g., relatively high temperatures, relatively large quantities of read operations performed on the block of memory cells) may degrade a performance of the block of memory cells.

At 215, if the memory system 110 performs the second type of error correction operation, a counter (e.g., a RAIN counter) may be adjusted. For example, when a second type of error correction is performed on a block for a first time, the counter may be established. In other instances, if the counter is established and the second type of error correction operation is performed, the counter may be adjusted (e.g., incremented). In some instances, the memory system 110 may maintain the RAIN counter until the block of memory cells is retried or refreshed. In response to incrementing the RAIN counter, the memory system 110 may examine one or more conditions of the block of memory cells.

At 220, in response to incrementing the RAIN counter, the memory system 110 may determine if a BER (e.g., a raw bit error rate (RBER)) of the block of memory cells satisfies a second threshold value. As described herein, a value may satisfy a threshold if the value is greater than or equal to the threshold. Accordingly, the memory system controller 115 may compare the BER to the threshold to determine whether the threshold value is satisfied. If the threshold value is satisfied, the process flow 200 may proceed to 230, whereas the process flow may proceed to 225 is the threshold value is not satisfied.

For example, the memory system 110 may compare the BER of the block of memory cells with one or more BERs of one or more neighboring blocks of memory cells in a same superblock (SB). As described herein, a SB may refer to a logical grouping of one or more blocks of memory cells. The memory system 110 may determine that the BER of the block of memory cells satisfies the second threshold value if the BER of the block of memory cells is relatively higher than the BERs of the one or more neighboring blocks of memory cells, which may indicate that the block of memory cells is potentially defective. That is, the second threshold value may be or may be associated with a BER of the one or more neighboring blocks of memory cells.

At 225, in response to incrementing the RAIN counter, the memory system 110 may determine if the RAIN counter satisfies a first threshold value. If neither of the RAIN counter nor the BER of the block of memory cells satisfy the first or second threshold values, respectively, the memory system 110 may refrain from retiring the block of memory cells. That is, if the block of memory cells does not have a relatively high BER or a relatively high counter value, the block may not be defective and the memory system 110 may refrain from retiring the block (e.g., the process flow 200 may return to 210).

If one or both of RAIN counter or the BER of the block of memory cells satisfy the first or second threshold values, the process flow 200 may proceed to 230.

At 230, the memory system 110 may perform one or more additional operations to determine whether the block (or a portion of the block) is defective. For example, based on the initial assessment of the BER and RAIN counter, the memory system 110 may analyze the first deck of memory cells (e.g., the deck of memory cells of the block of memory cells for which RAIN was triggered and the error was detected). That is, the memory system 110 may analyze one or more word lines of the first deck of memory cells to determine if a BER of one or more word lines of the first deck of memory cells satisfies a third threshold value. In some examples, the third threshold value may be the same as the second threshold value.

In some examples, the one or more word lines of the first deck of memory cells may be one or more word lines of an affected sub-block of the first deck of memory cells (e.g., a sub-block in which the error was detected) or one or more word lines of one or more other sub-blocks of the first deck of memory cells. In some examples, the one or more word lines of the first deck of memory cells may be adjacent to a first word line of the first deck of memory cells for which the memory system 110 detected the error. For example, for a page of the first deck of memory cells for which the memory system 110 detected an error on a word line N, the memory system 110 may examine a BER of a word line N−1 and a word line N+1. Additionally, or alternatively, (e.g., in response to determining that the BER of the word line N−1 or the word line N+1 satisfies the third threshold value), the memory system may examine a non-adjacent word line of the first deck of memory cells (e.g., a word line for which one or more additional word lines are located between the non-adjacent word line and the word line N−1 or the word line N+1).

If the BER of the one or more word lines of the first deck of memory cells does not satisfy the third threshold value, the memory system 110 may determine that the first deck of memory cell is not defective and may not retire the block (e.g., proceed to 210). If the BER of the one or more word lines of the first deck of memory cells does satisfy the third threshold value, the memory system 110 may determine that the first deck of memory cell is defective and therefore to retire the first deck of memory cells. In some examples, the memory system 110 may determine to retire the first deck of memory cells based on a BER of one or more of the word line N−1 and the word line N+1, or the non-adjacent word line, satisfying the third threshold value. The memory system 110 may proceed to 235 to check one or more other decks of the block of memory cells.

At 235, the memory system 110 may analyze one or more word lines (e.g., predefined word lines) of one or more other decks of memory cells of the block of memory cells. The memory system may determine if a BER of the one or more word lines of the one or more other decks of memory cells satisfies a fourth threshold value. In some examples, the fourth threshold value may be the same as the second threshold value.

In some examples, if the BER of the one or more word lines of the one or more other decks of memory cells does not satisfy the fourth threshold value, the process flow 200 may proceed to 245 where the memory system 110 may retire a portion of the block of memory cells. For example, the memory system 110 may retire the first deck of memory cells (e.g., mark the first deck of memory cells as bad or as a failing deck) and may not retire the one or more other decks of memory cells. As used herein, a “deck” of memory cells may refer to a portion of a physical memory array that includes a subset of its memory cells. By applying voltages to different physical word lines of a memory block in different combinations, a memory array may be divided into two, three, four, or more logical decks, each of which may be treated as independent.

The memory system 110 may accordingly repurpose the block of memory cells as a HGB (e.g., for a two-deck block) or as a TGB (e.g., for a three-deck block). In some examples, if a BER of a second deck of memory cells of the block of memory cells satisfies the fourth threshold value but a BER of a third deck of memory cells of the block of memory cells does not satisfy the fourth threshold value, the memory system 110 may retire the first and second decks of memory cells and may not retire the third deck of memory cells.

In some examples, if the BER of the one or more word lines of the one or more other decks of memory cells does satisfy the fourth threshold value, the process flow 200 may proceed to 240 where the memory system 110 may retire the full block of memory cells. Accordingly, the memory system 110 may retire blocks of memory cells after confirming that the blocks of memory cells are defective, which may prevent premature or belated block retirement and potential data loss (e.g., by retiring confirmed defective blocks). Additionally, the memory system 110 may partially retire a block of memory cells (e.g., rather than retiring a full block), which may enable utilizing one or more “good” decks of a block of memory cells with one or more “bad” or defective decks.

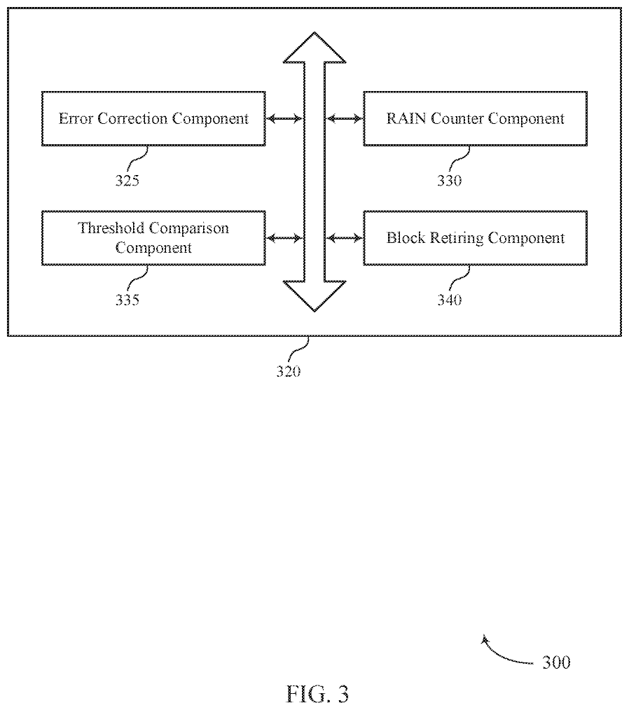

FIG. 3 shows a block diagram 300 of a memory system 320 that supports detection and retirement of defective blocks in accordance with examples as disclosed herein. The memory system 320 may be an example of aspects of a memory system as described with reference to FIGS. 1 through 2. The memory system 320, or various components thereof, may be an example of means for performing various aspects of detection and retirement of defective blocks as described herein. For example, the memory system 320 may include an error correction component 325, a RAIN counter component 330, a threshold comparison component 335, a block retiring component 340, or any combination thereof. Each of these components, or components of subcomponents thereof (e.g., one or more processors, one or more memories), may communicate, directly or indirectly, with one another (e.g., via one or more buses).

The error correction component 325 may be configured as or otherwise support a means for performing of a first type of error correction operation and a second type of error correction operation on a block of memory cells. The RAIN counter component 330 may be configured as or otherwise support a means for adjusting a value of a counter associated with the block in response to an error being present in the block after performing both of the first type of error correction operation and the second type of error correction operation. The threshold comparison component 335 may be configured as or otherwise support a means for determining whether the value of the counter satisfies a first threshold value and whether a first bit error rate associated with the block of memory cells satisfies a second threshold value in response to adjusting the value of the counter. The block retiring component 340 may be configured as or otherwise support a means for retiring a portion of the block of memory cells in accordance with the counter satisfying the first threshold value, the first bit error rate satisfying the second threshold value, or both.

In some examples, the error is associated with a first word line of the block of memory cells, and the threshold comparison component 335 may be configured as or otherwise support a means for determining that a second bit error rate associated with a second word line of the block of memory cells satisfies the second threshold value, where the second word line is adjacent to the first word line, and where retiring the portion of the block of memory cells is in accordance with the first bit error rate and the second bit error rate each satisfying the second threshold value.

In some examples, the threshold comparison component 335 may be configured as or otherwise support a means for determining that a third bit error rate associated with a third word line of the block of memory cells satisfies the second threshold value in response to determining that the second bit error rate satisfies the second threshold value, where one or more word lines are located between the second word line and the third word line, and where retiring at least the portion of the block of memory cells is in accordance with the first bit error rate, the second bit error rate, and the third bit error rate each satisfying the second threshold value.

In some examples, to support retiring at least the portion of the block of memory cells, the block retiring component 340 may be configured as or otherwise support a means for retiring the first deck of memory cells in accordance with the first bit error rate, the second bit error rate, and the third bit error rate each satisfying the second threshold value.

In some examples, the block of memory cells is operated as a half-good block (HGB) or a third-good block (TGB) in response to retiring the first deck of memory cells.

In some examples, the threshold comparison component 335 may be configured as or otherwise support a means for determining whether a fourth bit error rate associated with a fourth word line of a second deck of the block of memory cells satisfies the second threshold value in response to determining that the third bit error rate satisfies the second threshold value. In some examples, the block retiring component 340 may be configured as or otherwise support a means for retiring the block of memory cells in accordance with the fourth bit error rate satisfying the second threshold value.

In some examples, the block retiring component 340 may be configured as or otherwise support a means for refraining from retiring the second deck of memory cells in accordance with the fourth bit error rate failing to satisfy the second threshold value.

In some examples, the RAIN counter component 330 may be configured as or otherwise support a means for establishing the counter in response to performing the second type of error correction operation on the block of memory cells for a first time.

In some examples, the first type of error correction operation is configured to correct a first quantity of bit errors. In some examples, the second type of error correction operation is configured to correct a second quantity of bit errors that is greater than the first quantity of bit errors.

In some examples, the second type of error correction operation includes a RAIN error correction operation. In some examples, the value of the counter is associated with a quantity of RAIN operations.

In some examples, the second type of error correction operation is performed on the block in response to the first type of error correction operation unsuccessfully correcting the error.

In some examples, the block of memory cells is included in a superblock. In some examples, the second threshold value includes a bit error rate associated with one or more additional blocks included in the superblock.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

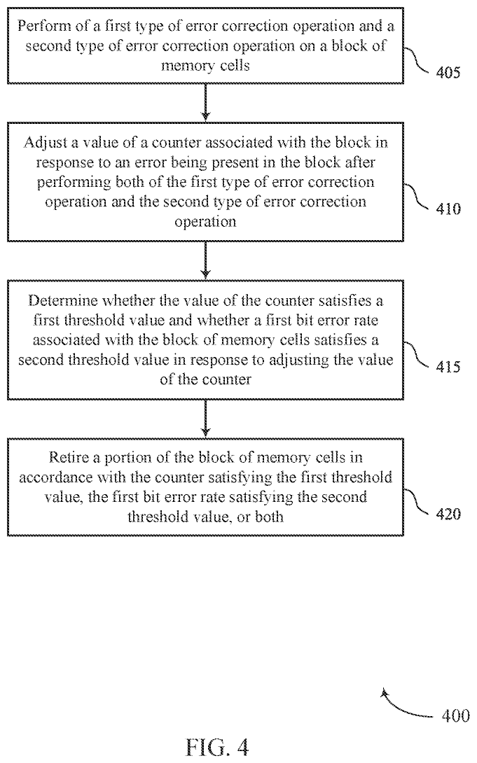

FIG. 4 shows a flowchart illustrating a method 400 that supports detection and retirement of defective blocks in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include performing of a first type of error correction operation and a second type of error correction operation on a block of memory cells. In some examples, aspects of the operations of 405 may be performed by an error correction component 325 as described with reference to FIG. 3.

At 410, the method may include adjusting a value of a counter associated with the block in response to an error being present in the block after performing both of the first type of error correction operation and the second type of error correction operation. In some examples, aspects of the operations of 410 may be performed by a RAIN counter component 330 as described with reference to FIG. 3.

At 415, the method may include determining whether the value of the counter satisfies a first threshold value and whether a first bit error rate associated with the block of memory cells satisfies a second threshold value in response to adjusting the value of the counter. In some examples, aspects of the operations of 415 may be performed by a threshold comparison component 335 as described with reference to FIG. 3.

At 420, the method may include retiring a portion of the block of memory cells in accordance with the counter satisfying the first threshold value, the first bit error rate satisfying the second threshold value, or both. In some examples, aspects of the operations of 420 may be performed by a block retiring component 340 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing of a first type of error correction operation and a second type of error correction operation on a block of memory cells; adjusting a value of a counter associated with the block in response to an error being present in the block after performing both of the first type of error correction operation and the second type of error correction operation; determining whether the value of the counter satisfies a first threshold value and whether a first bit error rate associated with the block of memory cells satisfies a second threshold value in response to adjusting the value of the counter; and retiring a portion of the block of memory cells in accordance with the counter satisfying the first threshold value, the first bit error rate satisfying the second threshold value, or both.

Aspect 2: The method, apparatus, or non-transitory computer-readable medium of aspect 1, where the error is associated with a first word line of the block of memory cells and the method, apparatuses, and non-transitory computer-readable medium further includes operations, features, circuitry, logic, means, or instructions, or any combination thereof for determining that a second bit error rate associated with a second word line of the block of memory cells satisfies the second threshold value, where the second word line is adjacent to the first word line, and where retiring the portion of the block of memory cells is in accordance with the first bit error rate and the second bit error rate each satisfying the second threshold value.

Aspect 3: The method, apparatus, or non-transitory computer-readable medium of aspect 2, further including operations, features, circuitry, logic, means, or instructions, or any combination thereof for determining that a third bit error rate associated with a third word line of the block of memory cells satisfies the second threshold value in response to determining that the second bit error rate satisfies the second threshold value, where one or more word lines are located between the second word line and the third word line, and where retiring at least the portion of the block of memory cells is in accordance with the first bit error rate, the second bit error rate, and the third bit error rate each satisfying the second threshold value.

Aspect 4: The method, apparatus, or non-transitory computer-readable medium of aspect 3, where retiring at least the portion of the block of memory cells includes operations, features, circuitry, logic, means, or instructions, or any combination thereof for retiring the first deck of memory cells in accordance with the first bit error rate, the second bit error rate, and the third bit error rate each satisfying the second threshold value.

Aspect 5: The method, apparatus, or non-transitory computer-readable medium of aspect 4, where the block of memory cells is operated as a half-good block (HGB) or a third-good block (TGB) in response to retiring the first deck of memory cells.

Aspect 6: The method, apparatus, or non-transitory computer-readable medium of any of aspects 3 through 5, further including operations, features, circuitry, logic, means, or instructions, or any combination thereof for determining whether a fourth bit error rate associated with a fourth word line of a second deck of the block of memory cells satisfies the second threshold value in response to determining that the third bit error rate satisfies the second threshold value and retiring the block of memory cells in accordance with the fourth bit error rate satisfying the second threshold value.

Aspect 7: The method, apparatus, or non-transitory computer-readable medium of aspect 6, further including operations, features, circuitry, logic, means, or instructions, or any combination thereof for refraining from retiring the second deck of memory cells in accordance with the fourth bit error rate failing to satisfy the second threshold value.

Aspect 8: The method, apparatus, or non-transitory computer-readable medium of any of aspects 1 through 7, further including operations, features, circuitry, logic, means, or instructions, or any combination thereof for establishing the counter in response to performing the second type of error correction operation on the block of memory cells for a first time.

Aspect 9: The method, apparatus, or non-transitory computer-readable medium of any of aspects 1 through 8, where the first type of error correction operation is configured to correct a first quantity of bit errors and the second type of error correction operation is configured to correct a second quantity of bit errors that is greater than the first quantity of bit errors.

Aspect 10: The method, apparatus, or non-transitory computer-readable medium of any of aspects 1 through 9, where the second type of error correction operation includes a RAIN error correction operation and the value of the counter is associated with a quantity of RAIN operations.

Aspect 11: The method, apparatus, or non-transitory computer-readable medium of any of aspects 1 through 10, where the second type of error correction operation is performed on the block in response to the first type of error correction operation unsuccessfully correcting the error.

Aspect 12: The method, apparatus, or non-transitory computer-readable medium of any of aspects 1 through 11, where the block of memory cells is included in a superblock and the second threshold value includes a bit error rate associated with one or more additional blocks included in the superblock.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method by a memory system, comprising:
performing of a first type of error correction operation and a second type of error correction operation on a block of memory cells;
adjusting a value of a counter associated with the block in response to an error being present in the block after performing both of the first type of error correction operation and the second type of error correction operation;
determining whether the value of the counter satisfies a first threshold value and whether a first bit error rate associated with the block of memory cells satisfies a second threshold value in response to adjusting the value of the counter; and
retiring a portion of the block of memory cells in accordance with the counter satisfying the first threshold value, the first bit error rate satisfying the second threshold value, or both.

2. The method of claim 1, wherein the error is associated with a first word line of the block of memory cells, the method further comprising:
determining that a second bit error rate associated with a second word line of the block of memory cells satisfies the second threshold value, wherein the second word line is adjacent to the first word line, and wherein retiring the portion of the block of memory cells is in accordance with the first bit error rate and the second bit error rate each satisfying the second threshold value.

3. The method of claim 2, further comprising:
determining that a third bit error rate associated with a third word line of the block of memory cells satisfies the second threshold value in response to determining that the second bit error rate satisfies the second threshold value, wherein one or more word lines are located between the second word line and the third word line, and wherein retiring at least the portion of the block of memory cells is in accordance with the first bit error rate, the second bit error rate, and the third bit error rate each satisfying the second threshold value.

4. The method of claim 3, wherein a first deck of memory cells of the block of memory cells comprises the first word line, the second word line, and the third word line, and wherein retiring at least the portion of the block of memory cells comprises:
retiring the first deck of memory cells in accordance with the first bit error rate, the second bit error rate, and the third bit error rate each satisfying the second threshold value.

5. The method of claim 4, wherein the block of memory cells is operated as a half-good block (HGB) or a third-good block (TGB) in response to retiring the first deck of memory cells.

6. The method of claim 3, further comprising:
determining whether a fourth bit error rate associated with a fourth word line of a second deck of the block of memory cells satisfies the second threshold value in response to determining that the third bit error rate satisfies the second threshold value; and
retiring the block of memory cells in accordance with the fourth bit error rate satisfying the second threshold value.

7. The method of claim 6, further comprising:
refraining from retiring the second deck of memory cells in accordance with the fourth bit error rate failing to satisfy the second threshold value.

8. The method of claim 1, further comprising:
establishing the counter in response to performing the second type of error correction operation on the block of memory cells for a first time.

9. The method of claim 1, wherein the first type of error correction operation is configured to correct a first quantity of bit errors, and wherein the second type of error correction operation is configured to correct a second quantity of bit errors that is greater than the first quantity of bit errors.

10. The method of claim 1, wherein the second type of error correction operation comprises a redundant array of independent negative-and (RAIN) error correction operation, and wherein the value of the counter is associated with a quantity of RAIN operations.

11. The method of claim 1, wherein the second type of error correction operation is performed on the block in response to the first type of error correction operation unsuccessfully correcting the error.

12. The method of claim 1, wherein the block of memory cells is included in a superblock, and wherein the second threshold value comprises a bit error rate associated with one or more additional blocks included in the superblock.

13. A memory system, comprising:
one or more memory devices; and
processing circuitry coupled with the one or more memory devices and configured to cause the memory system to:
perform of a first type of error correction operation and a second type of error correction operation on a block of memory cells;
adjust a value of a counter associated with the block in response to an error being present in the block after performing both of the first type of error correction operation and the second type of error correction operation;
determine whether the value of the counter satisfies a first threshold value and whether a first bit error rate associated with the block of memory cells satisfies a second threshold value in response to adjusting the value of the counter; and
retire a portion of the block of memory cells in accordance with the counter satisfying the first threshold value, the first bit error rate satisfying the second threshold value, or both.

14. The memory system of claim 13, wherein the error is associated with a first word line of the block of memory cells, and the processing circuitry is further configured to cause the memory system to:
determine that a second bit error rate associated with a second word line of the block of memory cells satisfies the second threshold value, wherein the second word line is adjacent to the first word line, and wherein retiring the portion of the block of memory cells is in accordance with the first bit error rate and the second bit error rate each satisfying the second threshold value.

15. The memory system of claim 14, wherein the processing circuitry is further configured to cause the memory system to:
determine that a third bit error rate associated with a third word line of the block of memory cells satisfies the second threshold value in response to determining that the second bit error rate satisfies the second threshold value, wherein one or more word lines are located between the second word line and the third word line, and wherein retiring at least the portion of the block of memory cells is in accordance with the first bit error rate, the second bit error rate, and the third bit error rate each satisfying the second threshold value.

16. The memory system of claim 15, wherein retiring at least the portion of the block of memory cells comprises the processing circuitry configured to cause the memory system to:
retire a first deck of memory cells in accordance with the first bit error rate, the second bit error rate, and the third bit error rate each satisfying the second threshold value.

17. The memory system of claim 16, wherein the block of memory cells is operated as a half-good block (HGB) or a third-good block (TGB) in response to retiring the first deck of memory cells.

18. The memory system of claim 15, wherein the processing circuitry is further configured to cause the memory system to:
determine whether a fourth bit error rate associated with a fourth word line of a second deck of the block of memory cells satisfies the second threshold value in response to determining that the third bit error rate satisfies the second threshold value; and
retire the block of memory cells in accordance with the fourth bit error rate satisfying the second threshold value.

19. The memory system of claim 18, wherein the processing circuitry is further configured to cause the memory system to:
refrain from retiring the second deck of memory cells in accordance with the fourth bit error rate failing to satisfy the second threshold value.

20. The memory system of claim 13, wherein the processing circuitry is further configured to cause the memory system to:
establish the counter in response to performing the second type of error correction operation on the block of memory cells for a first time.

21. The memory system of claim 13, wherein the first type of error correction operation is configured to correct a first quantity of bit errors, and wherein the second type of error correction operation is configured to correct a second quantity of bit errors that is greater than the first quantity of bit errors.

22. The memory system of claim 13, wherein the second type of error correction operation comprises a redundant array of independent negative-and (RAIN) error correction operation, and wherein the value of the counter is associated with a quantity of RAIN operations.

23. The memory system of claim 13, wherein the second type of error correction operation is performed on the block in response to the first type of error correction operation unsuccessfully correcting the error.

24. The memory system of claim 13, wherein the block of memory cells is included in a superblock, and wherein the second threshold value comprises a bit error rate associated with one or more additional blocks included in the superblock.

25. A non-transitory computer-readable medium storing code, the code comprising instructions executable by one or more processors to:
perform of a first type of error correction operation and a second type of error correction operation on a block of memory cells;
adjust a value of a counter associated with the block in response to an error being present in the block after performing both of the first type of error correction operation and the second type of error correction operation;
determine whether the value of the counter satisfies a first threshold value and whether a first bit error rate associated with the block of memory cells satisfies a second threshold value in response to adjusting the value of the counter; and
retire a portion of the block of memory cells in accordance with the counter satisfying the first threshold value, the first bit error rate satisfying the second threshold value, or both.
